(19) United States
(12) Patent Application Publication
(10) Pub. No.: US 2002/0123222 A1
(43) Pub. Date: Sep. 5, 2002

(54) Method of fabricating a salicide layer

(76) Inventor: Bing-Chang Wu, Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 09/795,143

(22) Filed: Mar. 1, 2001

(51) Int. Cl. H01L 21/76; H01L 21/3205; H01L 21/4763; H01L 21/44

(52) U.S. Cl. 438/682; 438/424; 438/592

(57) ABSTRACT

A method of fabricating a salicide layer is provided. A plurality of MOS transistors is formed on a semiconductor wafer followed by the coverage of an amorphous silicon layer on the MOS transistors and the semiconductor wafer. Thereafter, a first salicide process is performed to transform the portion of the amorphous silicon layer on the source and drain of each MOS transistor into a first salicide layer. Finally, a second salicide process is performed to form a second salicide layer, thicker than the first salicide layer, atop the gate of each MOS transistor.

### BACKGROUND OF THE INVENTION

1. Field of the Invention

The present invention relates to a semiconductor process, and more particularly, to a method of fabricating a salicide layer to improve the electrical performance of MOS devices.

2. Description of the Prior Art

A metal-oxide-semiconductor (MOS) transistor plays a very important role in integrated circuits. The electrical performance of gates especially affects the quality of the MOS transistors. The gate of a conventional MOS transistor usually comprises a polysilicon layer as a primary conductive layer, and a silicide layer positioned over the polysilicon layer. The silicide layer functions in providing a better ohmic contact so as to both lower the sheet resistance of the gate and increase the operational speed of the MOS transistor.

Please refer to FIG. 1 to FIG. 4. FIG. 1 to FIG. 4 are schematic diagrams of a method of fabricating a salicide layer 32 on a semiconductor substrate 10 according to the prior art. As shown in FIG. 1, both a memory array region 12 and a peripheral region 14 are defined on the semiconductor substrate 10. In both the memory array region 12 and the peripheral region 14, a plurality of MOS transistors 16 are formed on the surface of the semiconductor substrate 10. As well, a plurality of shallow trench isolation (STI) structures 18 are formed in the semiconductor substrate 10 to insulate the MOS transistors 16 from each other. Each MOS transistor 16 is composed of a conductive layer 20 positioned on the surface of the semiconductor substrate 10, two spacers 22 positioned on either side of the conductive layer 20, and two doped areas 24, 26 positioned in the semiconductor substrate 10 adjacent to the conductive layer 20 so as to function as a lightly doped drain (LDD) and source/drain (S/D) respectively.

As shown in FIG. 2, a dielectric layer 28 is then deposited on the surface of the semiconductor substrate 10. A photo and etching process (PEP) is performed to completely remove the dielectric layer 28 in the memory array region 12 as well as to remove a portion of the dielectric layer 28 in the peripheral region 14. The remaining dielectric layer 28 covers portions of the doped area 26 in the peripheral region 14 as a salicide block (SAB) 29, as shown in FIG. 3. Subsequently, a salicide process is performed by first using a physical vapor deposition (PVD) method to sputter a metal layer 30 on the surface of the semiconductor substrate 10. The metal layer 30 is composed of tungsten or titanium. A thermal treatment process is thereafter performed to allow the reaction of the metal layer 30 with the silicic materials. As a result, a salicide layer 32 is formed on the surfaces of both the conductive layer 20 and the doped area 26. Finally, the non-reacted metal layer 30 and the salicide block 29 are removed to finish the fabrication of the salicide layer 32 according to the prior art method.

For an embedded memory cell, the peripheral region 14 usually comprises electrostatic discharge (ESD) protection circuits to prevent the electrostatic discharge phenomenon from affecting the electrical performance of elements. Controlling the sheet resistance of a gate is an important factor in controlling the operational speed of the MOS transistor 16 in the peripheral region 14. However, the sheet resistance of the gate increases as the line width of the conductive layer 20 decreases. In order to lower the sheet resistance of the gate, the thickness of the salicide layer 32 positioned atop the gate must be increased. Simultaneously, the thickness of the salicide layer 32 formed on the source and drain is also increased. As a result, the thickness of the salicide layer 32 formed on the source and drain is too great so as to decrease the junction depth of the source and drain and induce leakage current.

### SUMMARY OF THE INVENTION

It is therefore an objective of the present invention to provide a method of fabricating a salicide layer to prevent the above-mentioned problems.

In a preferred embodiment, a semiconductor wafer comprising at least a memory array region and a peripheral region is provided. A plurality of MOS transistors are formed on the semiconductor wafer in both the memory array region and the peripheral region. Then, an amorphous silicon layer is formed to cover each MOS transistor. Thereafter, a first salicide process is performed to transform the portion of the amorphous silicon layer on the source and drain of each MOS transistor into a first salicide layer. Finally, a second salicide process is performed to form a second salicide layer, thicker than the first salicide layer, atop the gate of each MOS transistor.

It is an advantage of the present invention that the first salicide layer over the source and drain, and the second salicide layer atop the gate are formed, respectively, so as to obtain a proper thickness for both the first and second salicide layer. Specifically, a thinner first salicide layer is produced to prevent leakage current problems of the source and drain. In addition, a thicker second salicide layer is produced to decrease the sheet resistance of the gate. Hence, better electrical performance is achieved.

These and other objectives of the present invention will no doubt become obvious to those of ordinary skill in the art after reading the following detailed description of the preferred embodiment, which is illustrated in the various figures and drawings.

### BRIEF DESCRIPTION OF THE DRAWINGS

FIG. 1 to FIG. 4 are schematic diagrams of a method of fabricating a salicide layer according to the prior art.

FIG. 5 to FIG. 10 are schematic diagrams of a method of fabricating a salicide layer according to the present invention.

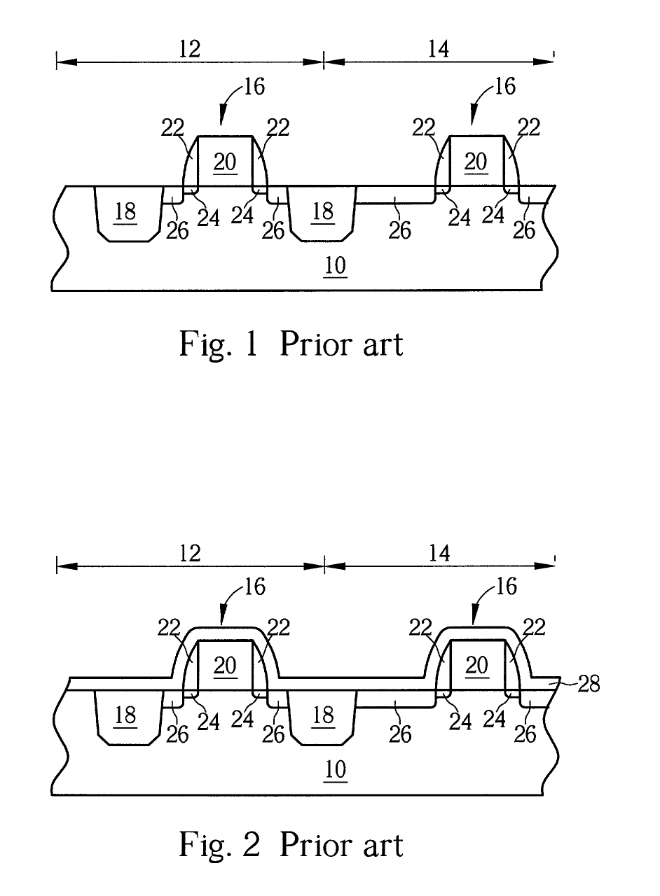

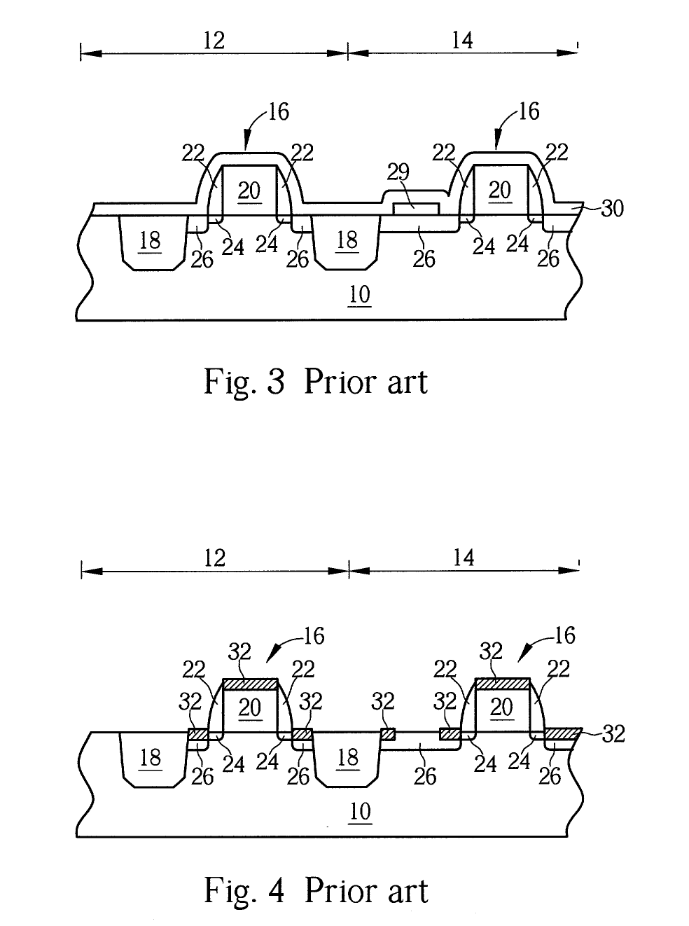

### DETAILED DESCRIPTION OF THE PREFERRED EMBODIMENT

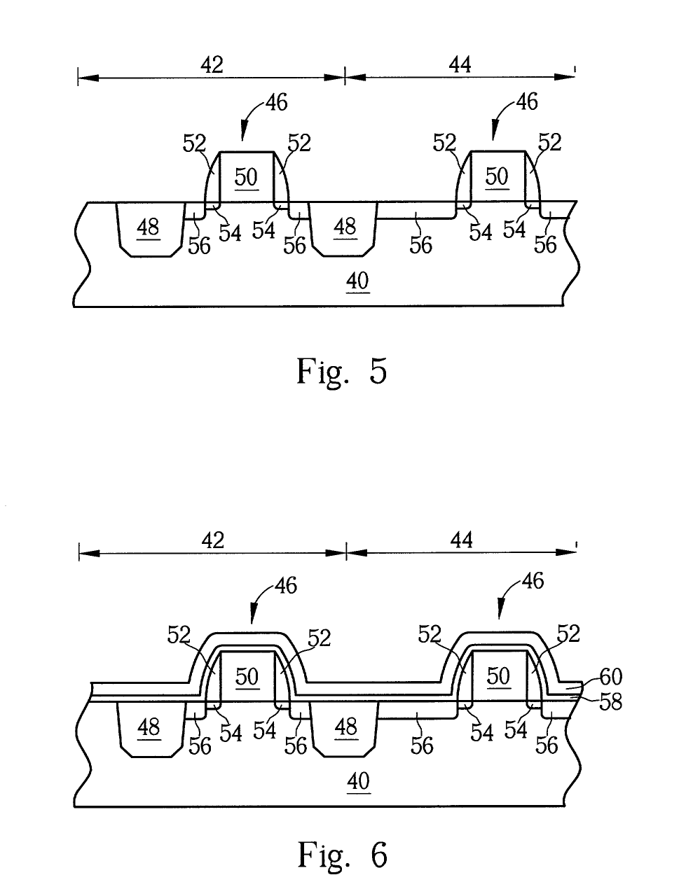

Please refer to FIG. 5 to FIG. 10. FIG. 5 to FIG. 10 are schematic diagrams of a method of fabricating salicide layers 62, 68 on a semiconductor substrate 40 according to the present invention. As shown in FIG. 5, both a memory array region 42 and a peripheral region 44 are defined on the semiconductor substrate 40. In both the memory array region 42 and the peripheral region 44, a plurality of MOS transistors 46 are formed on the surface of the semiconductor substrate 40. As well, a plurality of shallow trench isolation (STI) structures 48 are formed in the semiconductor substrate 40 to insulate the MOS transistors 46 from each other. Each MOS transistor 46 is composed of a conductive layer 50 positioned on the surface of the semiconductor substrate 40, two spacers 52 positioned on either side of the conductive layer 50, and two doped areas 54, 56 positioned in the semiconductor substrate 40 adjacent to the conductive layer 50 so as to function as a lightly doped drain (LDD) and source/drain (S/D) respectively.

As shown in FIG. 6, a low-pressure chemical vapor deposition (LPCVD) process is performed to form an amorphous silicon (α-Si) layer 58 and a dielectric layer 60 of silicon dioxide on the surface of the semiconductor substrate 40, respectively, to cover the memory array region 42, the peripheral region 44 and the conductive layer 50. The amorphous silicon layer 58 is 100 to 300 angstroms (Å) thick and the dielectric layer 60 is 300 to 1000 angstroms thick.

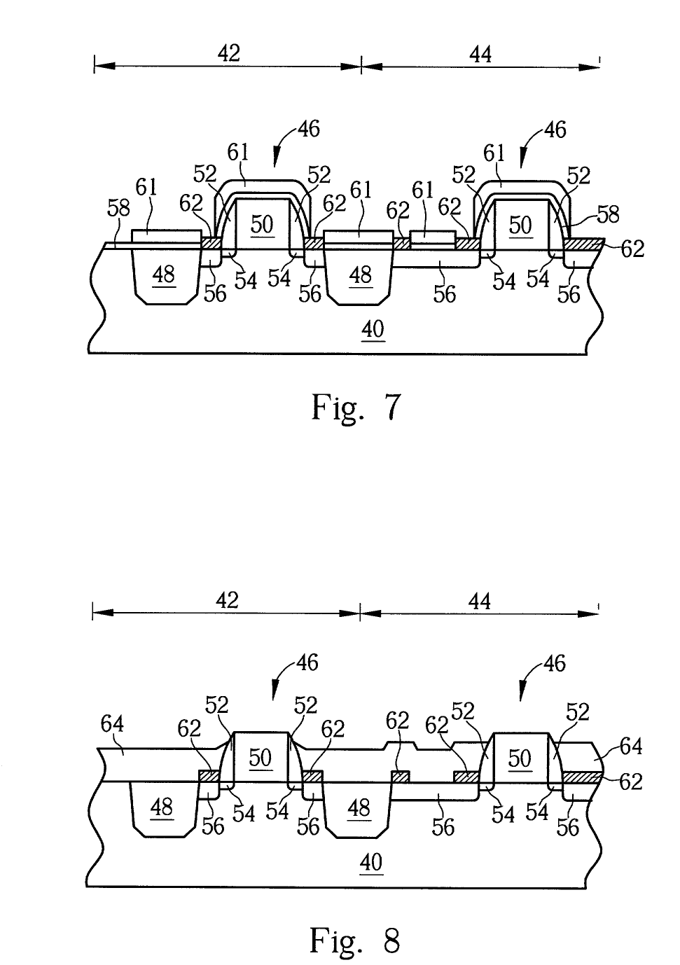

Then, as shown in FIG. 7, a photo and etching (PEP) process is performed to remove a portion of the dielectric layer 60 in the memory array region 42 and the peripheral region 44. A salicide block (SAB) 61 is thus formed on the amorphous silicon layer 58, covering both the conductive layer 50 and the shallow trench isolation structures 48. Simultaneously, the salicide block 61 is also formed on the amorphous silicon layer 58 over portions of the doped area 56 in the peripheral region 44. Thereafter, a first salicide process is performed to deposit a metal layer (not shown) of tungsten or titanium on the surface of the semiconductor substrate 40. Next, using the salicide block 61 as a mask, a thermal treatment process is performed to allow the reaction of the metal layer with the amorphous silicon layer 58. As a result, a salicide layer 62 of a thickness between 200 to 500 angstroms is formed.

As shown in FIG. 8, after the complete removal of the salicide block 61 and the non-reacted amorphous silicon layer 58, a chemical vapor deposition process is performed to deposit a dielectric layer 64 on the entire surface of the semiconductor substrate 40. The dielectric layer 64, composed of silicon dioxide, covers the top of each MOS transistor 46. A planarization process, such as an etching back method, is used thereafter to remove the dielectric layer 64 covering atop the MOS transistor 46. The surface of the conductive layer 50 of each MOS transistor 46 is exposed while the shallow trench isolation structures 48, the salicide layer 62 and portions of the doped area 56 in the peripheral region 44 are left covered by the remaining dielectric layer 64.

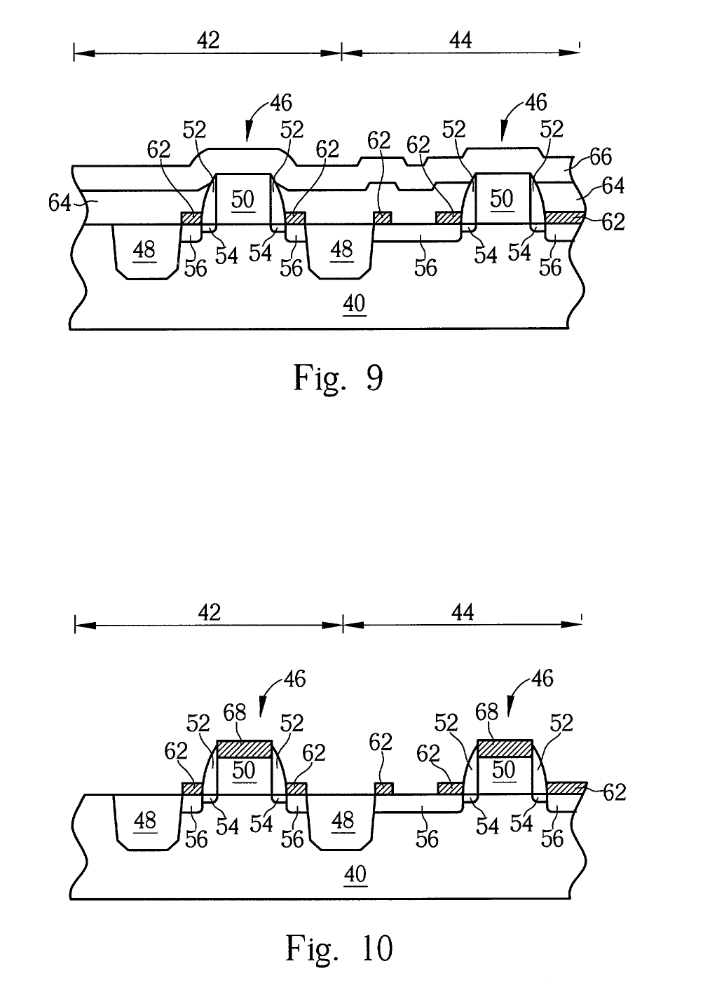

As shown in FIG. 9, a second salicide process is performed. A metal layer 66 of tungsten or titanium is deposited over the semiconductor substrate 40. Then, using the dielectric layer 64 as a salicide block, a thermal treatment process is performed to allow the reaction of the metal layer 66 with the surface of the silicic conductive layer 50. A salicide layer 68 of a thickness greater than 500 angstroms is thus produced, as shown in FIG. 10. Finally, both the non-reacted metal layer 66 and the dielectric layer 64 are completely removed to finish fabrication of the salicide layers of the present invention.

Since the amorphous silicon layer 58 is formed on the doped area 56 before performing the first salicide process, the titanium or tungsten metal layer reacts with the amorphous silicon layer 58 to produce the salicide layer 62 on the doped area 56. The deposition process of the metal layer thus controls the thickness of the salicide layer 62. Moreover, as the metal layer primarily reacts with the amorphous silicon layer 58 on the doped area 56, the salicide layer 62 does not effectively decrease the junction depth of the doped area 56 (source/drain).

In contrast to the prior art of fabricating a salicide layer, the method of the present invention uses two salicide processes to produce the first salicide layer covering the source and drain, and the second salicide layer covering atop the gate, respectively. Hence, both the first and the second salicide layer obtain a desired thickness to satisfy the electrical requirements. Specifically, a thinner first salicide layer is produced to prevent leakage current problems of the source and drain. A thicker second salicide layer is also produced to decrease the sheet resistance of the gate. Hence, better electrical performance is achieved.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of fabricating a salicide layer on a semiconductor wafer, the semiconductor wafer comprising at least a memory array region, a peripheral region, and a plurality of gates positioned in both the memory array region and the peripheral region, the method comprising:
forming an amorphous silicon (α-Si) layer on the surface of the semiconductor wafer to cover the memory array region, the peripheral region and the gates;
forming a first salicide block (SAB) on the amorphous silicon layer, the first salicide block covering at least the portions of the amorphous silicon layer over the gates;
performing a first salicide process to transform the portions of the amorphous silicon layer not covered by the first salicide block into a first silicide layer;
removing both the first salicide block and the non-reacted amorphous silicon layer;
forming a second salicide block on the surface of the semiconductor wafer to cover the memory array region, the peripheral region and the gates;
etching back the second salicide block to expose the tops of the gates; and
performing a second salicide process to form a second silicide layer on the exposed tops of the gates.

2. The method of claim 1 wherein the second silicide layer is thicker than the first silicide layer.

3. The method of claim 1 wherein the thickness of the first silicide layer is approximately 200 to 500 angstroms (Å).

4. The method of claim 1 wherein the second silicide layer is thicker than 500 angstroms.

5. The method of claim 1 wherein the first salicide block simultaneously covers both a shallow trench isolation (STI) region and portions of the peripheral region.

6. The method of claim 1 wherein both the first and second salicide blocks are composed of silicon oxide.

7. The method of claim 1 wherein the peripheral region is a region of electrostatic discharge (ESD) protection circuits.

8. A method of fabricating a salicide layer comprising:
providing a semiconductor substrate, which comprises at least an active area enclosed by a STI region;
forming a polysilicon gate in the active area;
forming a source and drain on the surface of the semiconductor substrate adjacent to the polysilicon gate;
forming an amorphous silicon (α-Si) layer on the surface of the semiconductor substrate to cover the polysilicon gate, the source and the drain in the active area as well as to cover the STI region;
performing a first salicide process to transform the portions of the amorphous silicon layer over the source and the drain into a first silicide layer; and
performing a second salicide process to form a second silicide layer on the top of the polysilicon gate;
wherein the second silicide layer is thicker than the first silicide layer.

9. The method of claim 8 wherein a first salicide block is formed before the first salicide process.

10. The method of claim 8 wherein a second salicide block is formed before the second salicide process.

11. The method of claim 8 wherein the thickness of the first silicide layer is approximately 200 to 500 angstroms.

12. The method of claim 8 wherein the second silicide layer is thicker than 500 angstroms.
